(19) United States
(12) Patent Application Publication
(10) Pub. No.: US 2026/0173864 A1
(43) Pub. Date: Jun. 18, 2026

(54) THERMAL SOLUTION FOR SEMICONDUCTOR PACKAGE AND METHOD OF FABRICATING THE SAME

(71) Applicant: International Business Machines Corporation, Armonk, NY (US)

(72) Inventors: Kalind BARAYA, West Lafayette, IN (US); Christine Louise TAYLOR, Poughkeepsie, NY (US); Shidong LI, Hopewell Junction, NY (US); Franklin M. BAEZ, Fishkill, NY (US)

(21) Appl. No.: 18/978,269

(22) Filed: Dec. 12, 2024

(51) Int. Cl. H10W 40/22; H10W 70/65; H10W 74/10; H10W 90/00

(52) U.S. Cl. CPC H10W 40/22; H10W 70/65; H10W 74/127; H10W 90/00

(57) ABSTRACT

A method and related IC module and electronic system are described, the method including electrically connecting a first IC device and a second IC device to a carrier. A first top surface of the first IC device has a first height, and a second top surface of the second IC device has a second height greater than the first height. The method further includes arranging a conformal thermal spreader over the first IC device and the second IC device. The conformal thermal spreader contacts the first top surface, the second top surface, and a seal band formed on the carrier around a perimeter of the first IC device and the second IC device. The method further includes connecting a frame to the carrier, wherein connecting the frame comprises connecting a perimeter wall of the frame to the seal band.

### BACKGROUND

The present disclosure relates to electronic devices, and more specifically, to the packaging of integrated circuit (IC) modules having multiple ICs.

An IC module may include one or more integrated circuit (IC) devices, such as chips, dies, processors, or the like, that are packaged onto a carrier. The IC module may provide heterogeneous integration (HI), where separately manufactured components are integrated into a higher-level assembly that provides improved functionality and/or operating characteristics.

The IC module may further include a lid that encapsulates the IC devices and that is attached to the carrier by a seal band. As the separately manufactured components may have different heights, the lid may be supported by an overmold material dispensed above the IC devices to provide a surface with a consistent height. The difference in heights can be even greater for three-dimensional IC devices that include a plurality of stacked, interconnected ICs to provide increased functionality for a given footprint within the IC module. However, the presence of the overmold material can impact the heat dissipation of the IC devices.

### SUMMARY

According to one embodiment of the present disclosure, a method comprises electrically connecting a first integrated circuit (IC) device and a second IC device to a carrier. A first top surface of the first IC device has a first height, and a second top surface of the second IC device has a second height greater than the first height. The method further comprises arranging a conformal thermal spreader over the first IC device and the second IC device. The conformal thermal spreader contacts the first top surface, the second top surface, and a seal band formed on the carrier around a perimeter of the first IC device and the second IC device. The method further comprises connecting a frame to the carrier, wherein connecting the frame comprises connecting a perimeter wall of the frame to the seal band.

According to another embodiment of the present disclosure, an integrated circuit (IC) module comprises a first IC device and a second IC device electrically connected to a carrier. A first top surface of the first IC device has a first height, and a second top surface of the second IC device has a second height greater than the first height. The IC module further comprises a seal band contacting the carrier around a perimeter of the first IC device and the second IC device, and a conformal thermal spreader contacting the first top surface, the second top surface, and the seal band. The IC module further comprises a frame having a perimeter wall connected to the seal band.

According to another embodiment of the present disclosure, an electronic system comprises a first integrated circuit (IC) device and a second IC device electrically connected to a carrier. A first top surface of the first IC device has a first height, and a second top surface of the second IC device has a second height greater than the first height. The electronic system further comprises a seal band contacting the carrier around a perimeter of the first IC device and the second IC device, and a conformal thermal spreader contacting the first top surface, the second top surface, and the seal band. The electronic system further comprises a frame having a perimeter wall connected to the seal band, a printed circuit board electrically connected to a bottom surface of the carrier, and a heat sink connected to a top surface of the frame.

### BRIEF DESCRIPTION OF THE DRAWINGS

FIG. 1 illustrates an example implementation of an integrated circuit (IC) module, according to one or more embodiments.

FIG. 2 illustrates another example implementation of an integrated circuit (IC) module, according to one or more embodiments.

FIG. 3 illustrates example implementations of a conformal thermal spreader, according to one or more embodiments.

FIG. 4 illustrates a method of fabricating an IC module, according to one or more embodiments.

FIGS. 5A-5H illustrates an exemplary sequence of fabricating an IC module, according to one or more embodiments.

### DETAILED DESCRIPTION

Embodiments of the disclosure are directed to an integrated circuit (IC) module (as well as an associated method of fabrication) that comprises a first IC device and a second IC device electrically connected to a carrier. A first top surface of the first IC device has a first height, and a second top surface of the second IC device having a second height greater than the first height. The IC module further comprises a seal band contacting the carrier around a perimeter of the first IC device and the second IC device, a conformal thermal spreader contacting the first top surface, the second top surface, and the seal band, and a frame having a perimeter wall connected to the seal band.

In some embodiments, the frame is formed of material(s) having a high thermal conductivity and provides a dissipation path for heat generated by the first IC device and the second IC device, to a heat sink or other cooling system component. In some embodiments, the frame is implemented as lid that encapsulates the first IC device and the second IC device. For example, an overmold material may be disposed partly over the first IC device between the first top surface and an underside of the lid. Instead of conducting the generated heat solely through the underside of the lid, the use of the conformal thermal spreader allows heat to be directed through the perimeter wall(s) of the lid toward the heat sink. This provides an improved dissipation path for the first IC device, as less heat is directed through the overmold material with a lesser thermal conductivity. The conformal thermal spreader may further provide an improved dissipation path for the second IC device.

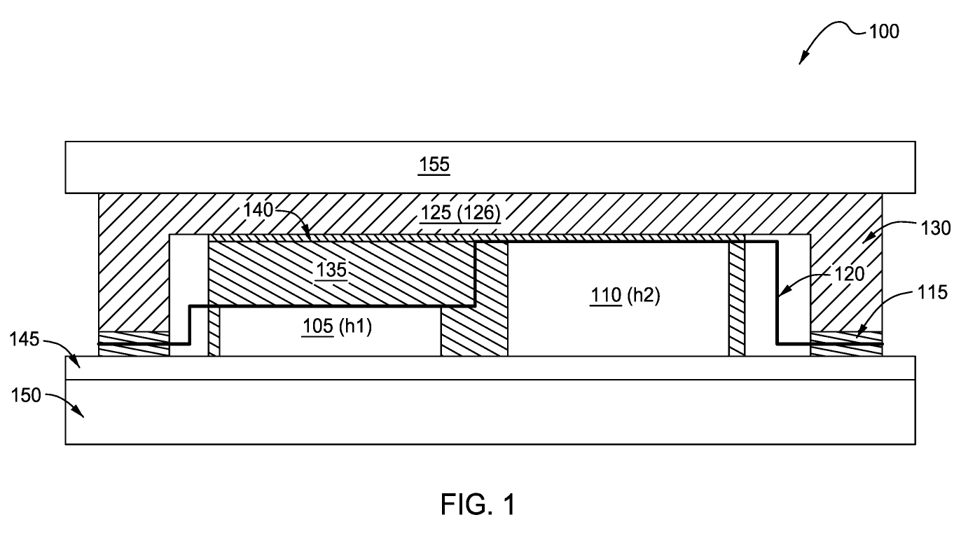

FIG. 1 illustrates an example implementation of an integrated circuit (IC) module 100, according to one or more embodiments. More specifically, FIG. 1 illustrates a cross-sectional view of the example implementation. The features of the IC module 100 may be used in conjunction with other embodiments.

The IC module 100 comprises a first IC device 105 and a second IC device 110 that are electrically connected to a carrier 145. In some embodiments, the carrier 145 comprises a substrate that supports the first IC device 105 and the second IC device 110, and electrical paths between an upper surface and a lower surface of the carrier. Although not shown, a plurality of interconnects electrically connect the first IC device 105 and the second IC device 110 to the upper surface of the carrier (e.g., arranged between respective conductive contacts or pads). Some examples of the plurality of interconnects include wire bonds, solder bonds, studs, balls, buttons, or the like. When the first IC device 105 and the second IC device 110 are seated on the carrier 145, a reflow process may be performed to join the plurality of interconnects with the respective electrical contacts or pads of the first IC device 105 and the second IC device 110 and the respective electrical contacts or pads of the carrier 145. A printed circuit board (PCB) 150 is electrically connected to a bottom surface of the carrier 145 using a second plurality of interconnects.

The first IC device 105 and the second IC device 110 may have any suitable implementation, such as a semiconductor die, a processor, a microchip, an application-specific integrated circuit (ASIC), a field-programmable gate array (FPGA), or the like. The first IC device 105 and the second IC device 110 may have the same or different implementations, and may have the same or different dimensioning, and so forth. As shown, the first IC device 105 has a first height h1, and the second IC device 110 has a second height h2.

In some embodiments, the first height h1 and the second height h2 differ from each other. In one non-limiting example, the first height h1 may be between about 100 um and about 400 um, and the second height h2 may be between about 500 um and 1000 um. In some embodiments, one or both of the first IC device 105 and the second IC device 110 comprises a three-dimensional IC device that include a plurality of stacked, interconnected ICs. In one non-limiting example, the first IC device 105 comprises a processor and the second IC device 110 comprises a die-stacked memory.

A seal band 115 contacts the carrier 145 around a perimeter of the first IC device 105 and the second IC device 110, and connects a frame 125 to the carrier 145. In some embodiments, the seal band 115 connects a bottom surface of a perimeter wall 130 of the frame 125 to the upper surface of the carrier 145. The frame 125 may include a single perimeter wall 130 that circumscribes the first IC device 105 and the second IC device 110, or multiple perimeter walls 130 that in combination circumscribe the first IC device 105 and the second IC device 110. The seal band 115 may be formed of material(s) providing any suitable elasticity, such as a polymeric compound, an elastomeric compound, an epoxy, an adhesive, and so forth.

In some embodiments, the seal band 115 is thermally conductive and allows heat to be dissipated through the perimeter wall 130 and the frame 125 toward a heat sink 155 or other cooling system component. For example, the material composition of the seal band 115 may include conductive materials such as aluminum oxide, aluminum nitride, silicon nitride, graphite, graphene, metallic particles, carbon nanotubes, and so forth. The frame 125 may be fabricated from a material having high thermal conductivity or a high heat transfer coefficient. For example, the frame 125 may be formed from a metal, such as copper, etc.

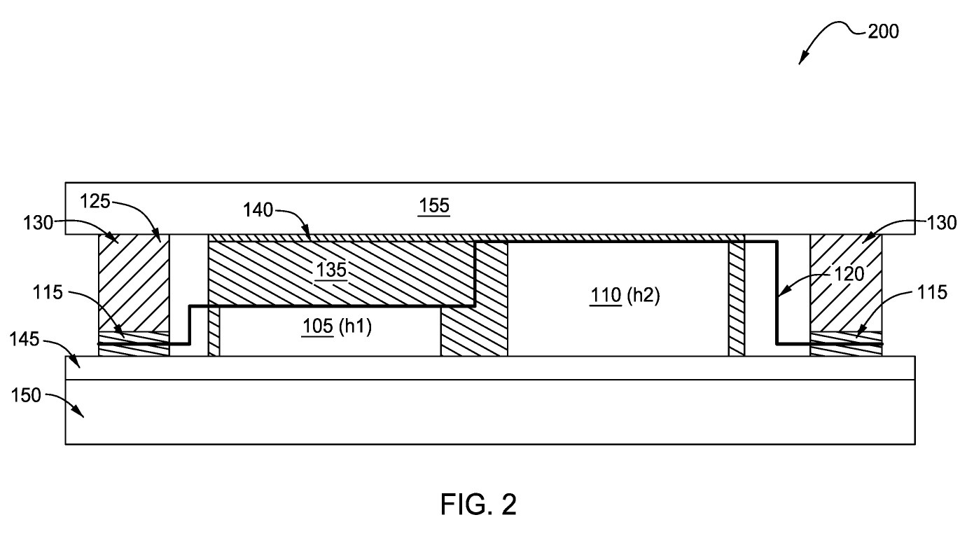

In some embodiments, the frame 125 comprises a lid 126 that covers and encapsulates the first IC device 105 and the second IC device 110. In other embodiments, such as in the IC module 200 of FIG. 2, the frame 125 circumscribes the first IC device 105 and the second IC device 110 without covering them. The lid 126 may include a substantially horizontal parallel plate section extending between the perimeter wall(s) 130 having any suitable profile, such as rectangular, circular, other polygonal, and so forth. In one non-limiting example, the parallel plate has a substantially rectangular profile and a thickness between about 500 um and 2 mm. The perimeter wall 130 extends from the lower surface of the parallel plate at the perimeter (or circumference) of the frame 125.

As shown, the first height h1 of the first IC device 105 is less than the second height h2 of the second IC device 110. One or more materials may be disposed over the first IC device 105 and/or the second IC device 110 to define a substantially planar surface, which in some cases contacts an underside of the lid 126 and supports the lid 126. In some embodiments, an overmold material 135 is disposed partly over the first IC device 105, and a thermal interface material 140 is disposed over the first IC device 105 and the second IC device 110.

The overmold material 135 may have any suitable implementation such as polyamides, epoxy resins, and so forth. As shown, the overmold material 135 encapsulates the first IC device 105 and partly encapsulates the second IC device 110, as the overmold material 135 contacts a top surface and side surfaces of the first IC device 105 and the side surfaces of the second IC device 110. In this way, the first IC device 105 may also be described as a “buried” die or IC. In some embodiments, the overmold material 135 may be dispensed to extend to an initial height, such that the overmold material 135 is arranged over both of the first IC device 105 and the second IC device 110, and a portion of the overmold material 135 is removed to extend to a final height where the overmold material 135 is not arranged over the second IC device 110.

The thermal interface material 140 may be implemented in any suitable form, such as a gel, a pad, a tape, an adhesive, a grease, a phase change material, and so forth. The thermal interface material 140 may have any suitable composition, such as a polymeric matrix having metallic or ceramic fillers. The thermal interface material 140 is arranged in a dissipation path for heat generated by the first IC device 105 and the second IC device 110. In one non-limiting example, the thermal interface material 140 has a thickness between about 100 um and 300 um. In embodiments such as the IC module 100, the thermal interface material 140 contacts an underside of the lid 126 and the overmold material 135 that is disposed over the first IC device 105, and defines the substantially planar surface that contacts the underside of the frame 125. In embodiments such as the IC module 200 of FIG. 2, the thermal interface material 140 contacts an underside of the heat sink 155 and the overmold material 135.

The overmold material typically 135 has a lesser thermal conductivity than the material(s) of the frame 125, such that dissipating heat from the first IC device 105 through the overmold material 135 incurs a thermal penalty that reduces the allowable power dissipation and/or the performance from the first IC device 105. In some embodiments, the IC module 100 further comprises a conformal thermal spreader 120 that is arranged above the first IC device 105 and/or the second IC device 110 and provides a heat dissipation path through the perimeter wall 130 and the frame 125, toward a heat sink 155 or other cooling system component. In some embodiments, the conformal thermal spreader 120 comprises a sheet (or film) of a thermally conductive material, such as copper, that contacts a first top surface of the first IC device 105 and a second top surface of the second IC device 110. Another example of the thermally conductive material comprises an anisotropic spreader material such as graphite. The characteristics of the conformal thermal spreader 120 may be selected to provide a desired thermal conductivity. In one non-limiting example, the conformal thermal spreader 120 thermally contacts substantially the entirety of the perimeter wall 130 and defines one or more openings extending therethrough (discussed in greater detail below), and the conformal thermal spreader 120 has a thickness of about 200 um to provide a thermal conductivity of about 40 Watts per meter Kelvin (W/mK). In other examples, the conformal thermal spreader 120 may contact only portions of the perimeter wall 130 and/or have a different thickness.

In some embodiments, the conformal thermal spreader 120 may be arranged to contact the perimeter wall 130 directly to form the heat dissipation path. In other embodiments, the conformal thermal spreader 120 may be arranged to contact the seal band 115, and thermally conducts through the seal band 115 to the perimeter wall 130 to form the heat dissipation path.

As mentioned above, the conformal thermal spreader 120 may define one or more openings extending therethrough. The one or more openings allow material to be deposited during fabrication after the application of the conformal thermal spreader 120, and to extend through the one or more openings to contact surfaces beneath the conformal thermal spreader 120. Using the one or more openings may be beneficial to provide thermal connection(s) to the perimeter wall 130 while still providing mechanical connection(s), and/or to optimize the fabrication process. In some embodiments, the overmold material 135 extends through the one or more openings to contact the first top surface of the first IC device 105, and/or to contact the second top surface of the second IC device 110. In some embodiments, the material of the seal band 115 extends through the one or more openings.

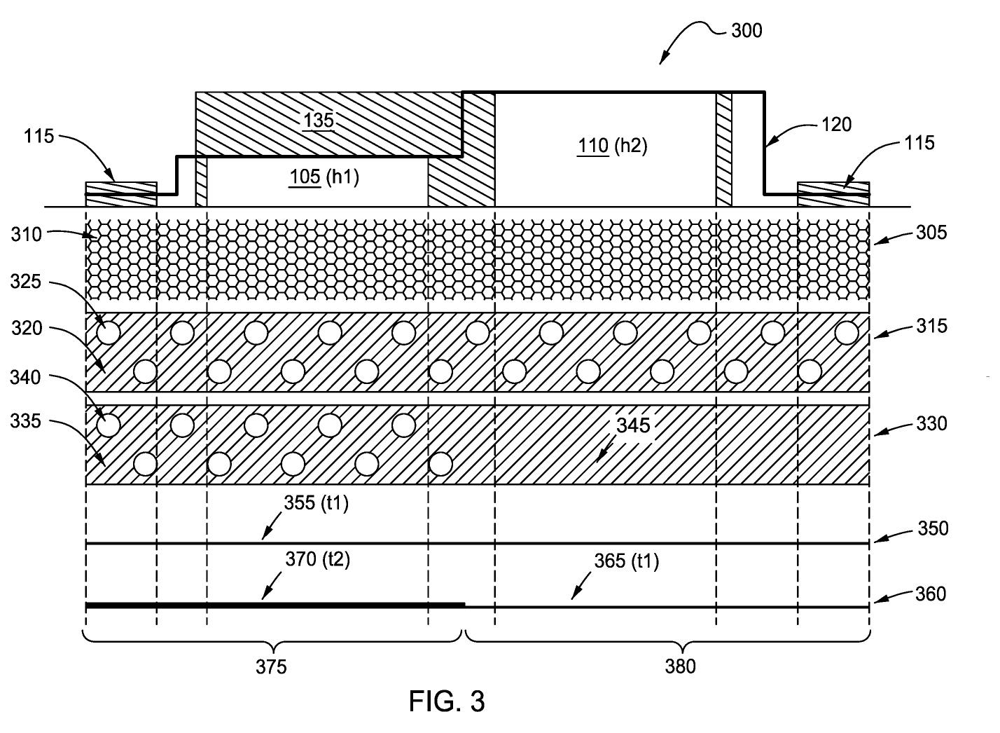

FIG. 3 illustrates example implementations of the conformal thermal spreader 120, according to one or more embodiments. More specifically, diagram 300 includes a cross-sectional view of several components of the IC module 100 or of the IC module 200, as well as several plots 305, 315, 330, 350, 360 that illustrate features of the example implementations of the conformal thermal spreader 120, relative to the components of the IC module 100 or IC module 200.

Plot 305 provides a top view of a section of the conformal thermal spreader 120, which is implemented here as a mesh 310 having a plurality of uniformly sized openings. The material of the mesh 310 and the openings may have any suitable dimensioning to support thermal connection between the first IC device 105 and the second IC device 110 and the seal band 115, as well as mechanical connection between the overmold material 135 and the first top surface of the first IC device 105 and/or the second top surface of the second IC device 110. As shown, the mesh 310 defines a regular pattern of hexagonal openings, but other implementations of the mesh 310 may define other regular patterns (e.g., rectangular, circular, slits) and/or irregular patterns. In some embodiments, the mesh 310 is uniform across the components of the IC module 100.

Plot 315 provides a top view of a section of the conformal thermal spreader 120, which is implemented here as a sheet 320 having staggered rows of circular openings 325. As depicted, the circular openings 325 are larger than the openings of the mesh 310 but spaced further apart. Beneficially, the additional material of the sheet 320 may provide improved thermal conductivity while supporting mechanical connections through the circular openings 325.

As with the mesh 310, the sheet 320 and the circular openings 325 are also shown as being uniform across the components of the IC module 100. However, in other embodiments, the mesh 310 or the sheet 320 may be patterned differently for different portions of the conformal thermal spreader 120. For example, plot 330 provides a top view of a section of the conformal thermal spreader 120, which has a first portion 375 overlapping the first IC device 105 and a portion of the seal band 115, and a second portion 380 overlaps the second IC device 110 and another portion of the seal band 115. The characteristics of the first portion 375 and the second portion 380 may be selected based on the desired thermal conductivity and/or mechanical connectivity. For example, in plot 330 the first portion 375 is implemented as a sheet 335 having staggered rows of circular openings 340 providing mechanical connectivity to the first IC device 105, and the second portion 380 implemented as a sheet 345 without openings (e.g., where mechanical connections to the second IC device 110 are not required).

Further, the thickness of the conformal thermal spreader 120 may be controlled based on the desired thermal conductivity and/or mechanical connectivity. Control of the thickness may be in conjunction with different features of the conformal thermal spreader 120 such as those depicted in the plots 305, 315, 330. In some embodiments, and as shown in the thickness profile 355 of plot 350, the conformal thermal spreader 120 has a uniform thickness t1 across the first portion 375 and the second portion 380. In other embodiments, and as shown in the thickness profiles 365, 370 of plot 350, the second portion 380 has the first thickness t1 and the first portion 375 has a second thickness t2 greater than the first thickness t2. The greater second thickness t2 may provide improved thermal conductivity for dissipating heat from the first IC device 105.

Particular features and combinations of features are shown in the plots 305, 315, 330, 350, 360 for simplicity. However, different features and combinations are also contemplated. For example, the conformal thermal spreader 120 may include a mesh and a sheet (with or without openings), meshes of different configurations, more than two portions, portion(s) with transitions (e.g., gradually decreasing size of openings), and so forth.

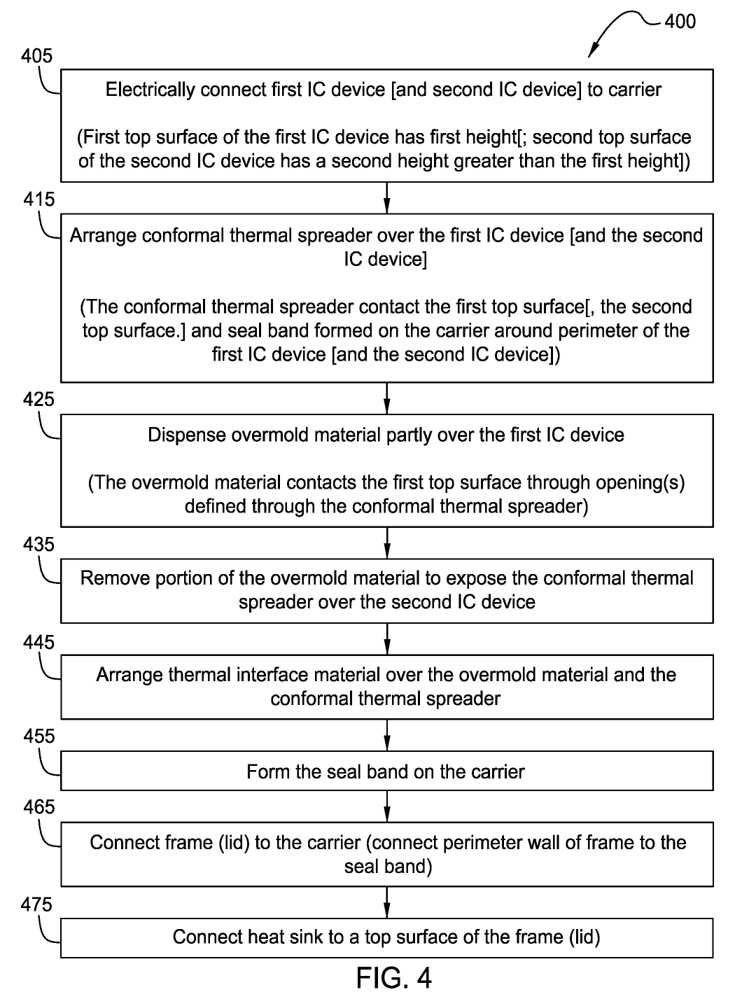

FIG. 4 illustrates a method 400 of fabricating an IC module, according to one or more embodiments. The features of the method 400 may be used in conjunction with other embodiments. For example, the method 400 may be used to fabricate the IC module 100 of FIG. 1 or the IC module 200 of FIG. 2.

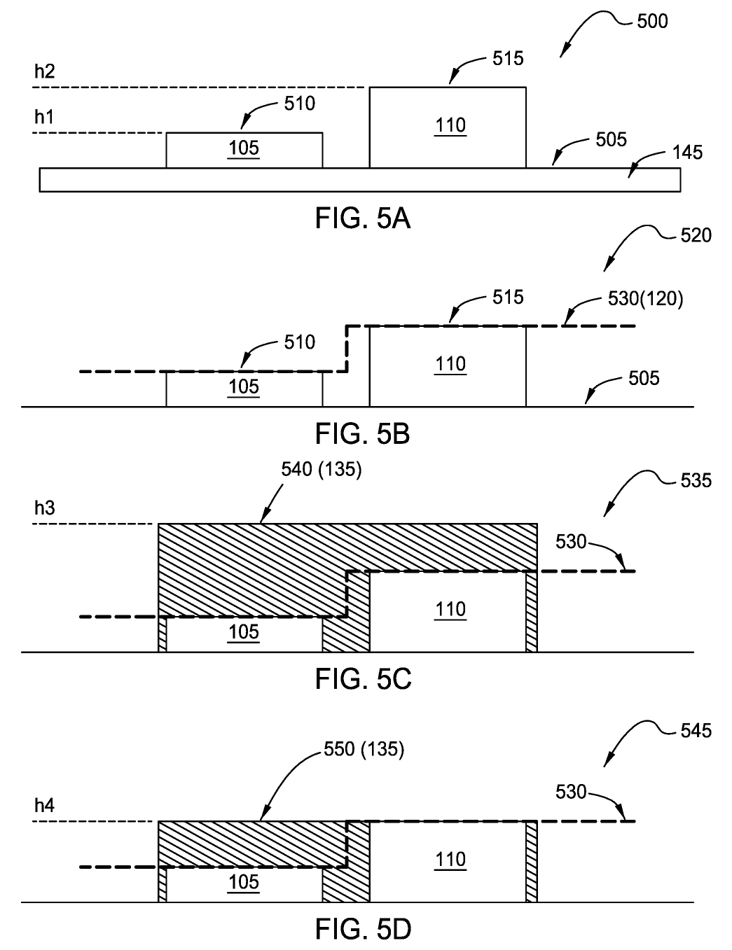

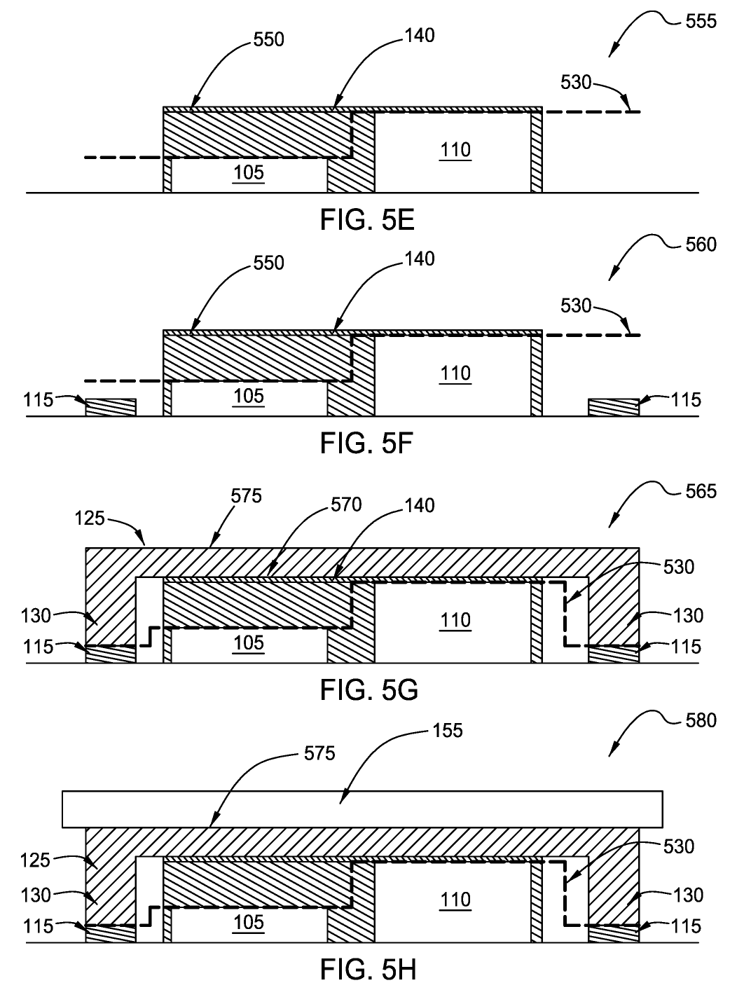

The method 400 begins at block 405. Referring also to diagram 500 of FIG. 5A, at block 405 a first IC device 105 (and optionally, a second IC device 110) are electrically connected to a carrier 145. In some embodiments, electrically connecting the first IC device 105 and the second IC device 110 comprises joining a plurality of interconnects between conductive contacts (or pads) of the first IC device 105 and the carrier 145. When electrically connected, a first top surface 510 of the first IC device has a first height h1 relative to an upper surface 505 of the carrier 145, and a second top surface 515 of the second IC device 110 has a second height h2 that is greater than the first height h1.

At block 415, and referring also to diagram 520 of FIG. 5B, a conformal thermal spreader 530 is arranged over the first IC device 105, and optionally the second IC device 110. The conformal thermal spreader 530 represents one example of the conformal thermal spreader 120 having one or more openings formed therethrough. In some embodiments, the conformal thermal spreader 530 contacts the first top surface 510 and optionally the second top surface 515. In some embodiments, arranging the conformal thermal spreader 530 includes pressing the conformal thermal spreader 530 toward the first top surface 510 and the second top surface 515, e.g., using a roller or mechanical finger.

At block 425, and referring also to diagram 535 of FIG. 5C, an overmold material 540 is dispensed partly over the first IC device 105. The overmold material 540 represents one example of the overmold material 135. As shown, the overmold material 540 extends to a third height h3. In some embodiments, the overmold material 540 contacts the first top surface 510 and the second top surface 515 through the one or more openings defined through the conformal thermal spreader 530.

At block 435, and referring also to diagram 545 of FIG. 5D, a portion of the overmold material 540 is removed to expose the conformal thermal spreader 530 over the second IC device 110. As shown, the third height h3 of the overmold material 540 is reduced to a fourth height h4 of the overmold material 550, which in some embodiments may be equal to the sum of the height h2 of the second IC device 110 and the thickness of the conformal thermal spreader 530.

At block 445, and referring also to diagram 555 of FIG. 5E, a thermal interface material 140 is arranged over the overmold material 550 and the conformal thermal spreader 530. At block 455, and referring also to diagram 560 of FIG. 5F, the seal band 115 is formed on the carrier 145 around a perimeter of the first IC device 105 and the second IC device 110. In some embodiments, the material of the seal band 115 is deposited partly or fully through the one or more openings of the conformal thermal spreader 530.

At block 465, and referring also to diagram 565 of FIG. 5G, the frame 125 is connected to the carrier 145. In some embodiments, connecting the frame 125 comprises connecting a perimeter wall 130 of the frame 125 to the seal band 115. In embodiments where the frame 125 is implemented as a lid 126, connecting the frame 125 comprises contacting the thermal interface material 140 to an underside 570 of the lid 126. At block 475, and referring also to diagram 580 of FIG. 5H, the heat sink 155 is connected to a top surface 575 of the frame 125. The top surface 575 may include a top surfaces of a lid and/or of perimeter wall(s) 130 of the frame 125. In some embodiments, where the frame 125 circumscribes the first IC device 105 and the second IC device 110 without covering them, connecting the heat sink 155 to the top surface of the frame 125 further comprises connecting the heat sink 155 to the thermal interface material 140. The method 400 ends following completion of block 475.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

Reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the aspects, features, embodiments and advantages disclosed herein are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.”

While the foregoing is directed to embodiments of the present invention, other and further embodiments of the invention may be devised without departing from the basic scope thereof, and the scope thereof is determined by the claims that follow.

What is claimed is:

1. A method comprising:
electrically connecting a first integrated circuit (IC) device and a second IC device to a carrier, a first top surface of the first IC device having a first height, and a second top surface of the second IC device having a second height greater than the first height;
arranging a conformal thermal spreader over the first IC device and the second IC device, the conformal thermal spreader contacting the first top surface, the second top surface, and a seal band formed on the carrier around a perimeter of the first IC device and the second IC device; and
connecting a frame to the carrier, wherein connecting the frame comprises connecting a perimeter wall of the frame to the seal band.

2. The method of claim 1, further comprising:
dispensing an overmold material partly over the first IC device, wherein the overmold material contacts the first top surface through one or more openings defined through the conformal thermal spreader; and
arranging a thermal interface material over the overmold material and the conformal thermal spreader,
wherein the frame comprises a lid that encapsulates the first IC device and the second IC device, and
wherein connecting the frame further comprises contacting the thermal interface material to an underside of the lid.

3. The method of claim 2, further comprising:
removing a portion of the overmold material to expose the conformal thermal spreader over the second IC device.

4. The method of claim 2, further comprising:
forming the seal band on the carrier after arranging the thermal interface material over the overmold material.

5. The method of claim 2, wherein the conformal thermal spreader comprises a mesh with a plurality of uniformly sized openings.

6. The method of claim 5, wherein the mesh is formed of a thermally conductive material or of an anisotropic spreader material.

7. The method of claim 1, wherein a first thickness of the conformal thermal spreader over the first top surface is greater than a second thickness of the conformal thermal spreader over the second top surface.

8. The method of claim 1, further comprising:
connecting a heat sink to a top surface of the frame.

9. The method of claim 1, wherein the first IC device comprises a processor, and the second IC device comprises a die-stacked memory.

10. An integrated circuit (IC) module comprising:
a first IC device and a second IC device electrically connected to a carrier, a first top surface of the first IC device having a first height, and a second top surface of the second IC device having a second height greater than the first height;
a seal band contacting the carrier around a perimeter of the first IC device and the second IC device;
a conformal thermal spreader contacting the first top surface, the second top surface, and the seal band; and
a frame having a perimeter wall connected to the seal band.

11. The IC module of claim 10, wherein the frame comprises a lid that encapsulates the first IC device and the second IC device, the IC module further comprising:
an overmold material disposed partly over the first IC device and contacting the first top surface through one or more openings defined through the conformal thermal spreader; and
a thermal interface material contacting: an underside of the lid, the overmold material disposed over the first IC device, and the conformal thermal spreader over the second IC device.

12. The IC module of claim 11, wherein the conformal thermal spreader comprises a mesh with a plurality of uniformly sized openings.

13. The IC module of claim 12, wherein the mesh is formed of a thermally conductive material or of an anisotropic spreader material.

14. The IC module of claim 10, wherein a first thickness of the conformal thermal spreader over the first top surface is greater than a second thickness of the conformal thermal spreader over the second top surface.

15. The IC module of claim 10, wherein the first IC device comprises a processor, and the second IC device comprises a die-stacked memory.

16. An electronic system comprising:
a first integrated circuit (IC) device and a second IC device electrically connected to a carrier, a first top surface of the first IC device having a first height, and a second top surface of the second IC device having a second height greater than the first height;
a seal band contacting the carrier around a perimeter of the first IC device and the second IC device;
a conformal thermal spreader contacting the first top surface, the second top surface, and the seal band;
a frame having a perimeter wall connected to the seal band;
a printed circuit board electrically connected to a bottom surface of the carrier; and
a heat sink connected to a top surface of the frame.

17. The electronic system of claim 16, wherein the frame comprises a lid that encapsulates the first IC device and the second IC device, the electronic system further comprising:
an overmold material disposed partly over the first IC device and contacting the first top surface through one or more openings defined through the conformal thermal spreader; and
a thermal interface material contacting: an underside of the lid, the overmold material disposed over the first IC device, and the conformal thermal spreader over the second IC device.

18. The electronic system of claim 17, wherein the conformal thermal spreader comprises a mesh with a plurality of uniformly sized openings.

19. The electronic system of claim 16, wherein a first thickness of the conformal thermal spreader over the first top surface is greater than a second thickness of the conformal thermal spreader over the second top surface.

20. The electronic system of claim 16, wherein the first IC device comprises a processor, and the second IC device comprises a die-stacked memory.
